(19) United States
(12) Patent Application Publication
(10) Pub. No.: US 2026/0223617 A1
(43) Pub. Date: Jul. 30, 2026

(54) DICING METHOD, SEMICONDUCTOR STRUCTURE AND DIE

(71) Applicant: WUHAN XINXIN SEMICONDUCTOR MANUFACTURING CO., LTD., Wuhan (CN)

(72) Inventors: Shengjin SONG, Wuhan (CN); Sheng HU, Wuhan (CN)

(21) Appl. No.: 19/409,137

(22) Filed: Dec. 4, 2025

(30) Foreign Application Priority Data
Dec. 12, 2024 (CN) 202411836885.9

(51) Int. Cl. H10P 58/00; H10P 50/24; H10P 50/28; H10P 54/20; H10W 74/10

(52) U.S. Cl. CPC H10P 58/20; H10P 54/20; H10W 74/134; H10W 74/141; H10P 50/24; H10P 50/28

(57) ABSTRACT

A dicing method, a semiconductor structure and a die are provided. In the dicing method, a first groove is formed in each second region of a substrate and is filled with a first dielectric layer, and a second groove is then formed in the first dielectric layer in each first groove. The first groove is formed by removing corresponding portions of the substrate in the first groove, which may be complex in structure and contain various materials. The second groove is formed simply by etching the interlayer dielectric layer in the first groove.

### TECHNICAL FIELD

The present invention relates to the field of semiconductor technology and, in particular, to a dicing method, a semiconductor structure and a die.

### BACKGROUND

After dies are formed on a semiconductor substrate through a programmed sequence of processes, the substrate is diced to separate and singularize the dies. The individual dies are then separately packaged, or further bonded and connected to one or more other dies and/or substrates into a system-in-package (SIP). Currently available dicing methods mainly include blade dicing, laser cutting, plasma dicing and stealth dicing (involving focusing infrared (IR) laser radiation within a wafer to destroy its lattice, separating dies during wafer expansion).

As technology develops, dicing is increasingly required to be done with minimized destructiveness and die contamination. Moreover, typically metal-containing structures such as test keys, alignment marks, measurement marks and feature patterns are usually arranged in dicing lanes, in order to result in area savings. Among those dicing methods, blade dicing and laser cutting are associated with considerable destructiveness and contamination. Despite minor contamination, plasma dicing and stealth dicing both require metal-free (or blank) dicing lanes. At present, there remains a lack of dicing methods suitable for substrate with different dicing area materials and capable of less destructive dicing with less contamination.

### SUMMARY OF THE INVENTION

The present invention provides a dicing method suitable for substrate with different dicing area materials and capable of less destructive dicing with less contamination. Also provided are a semiconductor structure and a die.

In one aspect, the present invention provides a dicing method comprising:
obtaining a substrate that comprises at least two first regions and at least one second region located between adjacent first regions, wherein the substrate has a front side and a backside opposite to the front side;
forming a first groove in each second region of the substrate, wherein the first groove extends from the front side into the substrate;
forming a first dielectric layer that at least fills the first groove; and
forming a second groove in the first dielectric layer in each first groove, wherein the second groove extends from a surface of the first dielectric layer into the substrate.

Optionally, the substrate may comprise a base substrate, an interlayer dielectric layer formed over the base substrate and a metal layer formed in the interlayer dielectric layer in the second region, wherein the first groove is formed in the second region of the substrate by removing a portion of the interlayer dielectric layer and a portion of the metal layer in the second region through a laser dicing process.

Optionally, slag and surface particles produced during the laser dicing process may be removed before the first dielectric layer is formed.

Optionally, the first groove may at least extend through the interlayer dielectric layer.

Optionally, before the second groove is formed, a second dielectric layer is formed in the first and second regions, wherein at least one conductive pad is formed in the second dielectric layer in the first region, wherein the second dielectric layer corresponding to the second groove is metal-free, and wherein the second groove extends from a surface of the second dielectric layer into the substrate.

Optionally, before the second groove is formed, forming a third dielectric layer in the first and second regions, wherein the third dielectric layer covers the conductive pad; and
performing a plasma dicing process from a surface of the third dielectric layer that corresponds to the first groove into the substrate, thereby forming the second groove until the substrate is separated.

Optionally, before the substrate is separated by the plasma dicing process, the substrate is thinned from the backside and then the backside of the thinned substrate is placed on a carrier tape.

Optionally, the substrate may be a wafer, wherein the first regions are die regions and the second regions are dicing lanes.

In another aspect, the present invention provides a semiconductor structure comprising:
a substrate that comprises at least two first regions and at least one second region located between adjacent first regions, wherein the substrate has a front side and a backside opposite to the front side;
a first groove formed in the second region of the substrate and extending from the front side into the substrate;
a first dielectric layer at least filling the first groove; and
a second groove formed in the first dielectric layer in the first groove and extending from a surface of the first dielectric layer into the substrate.

Optionally, the substrate may comprise a base substrate and an interlayer dielectric layer located on the base substrate, wherein the first groove at least extends through the interlayer dielectric layer.

Optionally, the semiconductor structure may further comprise a second dielectric layer formed in the first and second regions and covering the first dielectric layer, wherein the second groove extends from a surface of the second dielectric layer into the substrate; and at least one conductive pad formed in the second dielectric layer in the first region, wherein the second dielectric layer corresponding to the second region is metal-free.

Optionally, the semiconductor structure may further a third dielectric layer formed in the first and second regions and covering the conductive pad, wherein the second groove extends from a surface of the second dielectric layer into the substrate.

In yet another aspect, the present invention provides a die comprising:
a first die surface and a second die surface opposite to the first die surface;
a first surface that is a surface of a first groove formed by removing a portion of a substrate; and
a second surface that is a surface of a second groove formed by etching a first dielectric layer filled in the first groove, wherein the first and second surfaces are located between the first and second die surfaces and intersect with each other at an edge of the die, and wherein the first dielectric layer is provided between the first and second surfaces.

The present invention provides a dicing method, in which first grooves are formed in second regions of a substrate and filled with a first dielectric layer, and second grooves are then formed in the first dielectric layer in the first grooves. The first grooves are formed by removing corresponding portions of the substrate in the first grooves, and the second grooves are formed simply by etching the first dielectric layer in the first grooves. Compared with forming the second grooves by directly removing corresponding portions of the substrate in the second regions, this dicing method can be suitably used to dice regions of various different materials and enables easier dicing of a substrate with less destructiveness and contamination, resulting in improved dicing quality.

The present invention also provides a semiconductor structure comprising a substrate, first grooves formed in second regions of the substrate, a first dielectric layer filling the first grooves and second grooves formed in the first dielectric layer in the first grooves. The substrate can be separated along the second grooves. With this arrangement, the substrate can be diced in a manner with less destructiveness and contamination, and the semiconductor structure has improved quality.

The present invention also provides a die comprising opposite first and second die surfaces and opposite first and second surfaces. The first surface is a surface of a first groove formed by removing part of a substrate, and the second surface is a surface of a second groove formed by etching a first dielectric layer filled in the first groove. The first and second surfaces are located between the first and second die surfaces and intersect with each other at an edge of the die. The die is obtainable according to the dicing method as defined above. Through forming the first and second grooves, the die can be obtained in a manner with less destructiveness and contamination and has high quality.

### BRIEF DESCRIPTION OF THE DRAWINGS

FIG. 1 shows a schematic flowchart of a dicing method according to embodiments of the present invention.

FIGS. 2A to 2K are schematic cross-sectional views illustrating a dicing method according to embodiments of the present invention.

### DETAILED DESCRIPTION

Dicing methods, semiconductor structures and dies according to specific embodiments of the present invention will be described in greater detail below with reference to the accompanying drawings. From the following description, advantages and features of the present invention will become more apparent. It will be understood that the figures are provided in a very simplified form not necessarily drawn to exact scale for the only purpose of helping to explain the embodiments disclosed herein in a more convenient and clearer way. Note that the order of steps in the method as presented herein is not the only order in which these steps must be performed. Rather, some of the steps may be omitted, and/or other steps that are not described herein may be added. It will be understood that, as used herein, spatially relative terms are intended to encompass different orientations of the device in use or operation in addition to the orientation depicted in the figures. For example, if the device in the figures is inverted or otherwise oriented (e.g., rotated), the exemplary term “over” can encompass an orientation of “under” and other orientations.

Currently, dicing a semiconductor structure wafer separately using blade dicing, laser cutting, plasma dicing or stealth dicing (involving focusing infrared (IR) laser radiation within a wafer to destroy its lattice, separating dies during wafer expansion) remains problematic. For example, blade dicing produces rough diced surfaces, is prone to notching, cracking, passivation, metal layer delamination and other issues, and tends to cause defects and contamination at bonding interfaces. Laser cutting produces undesired heat, more or less rough diced surfaces and slag accumulating on die surfaces, while cleaning such slag tends to cause spreading of contaminants. Despite minor contamination, plasma dicing and stealth dicing both require metal-free (or blank) dicing lanes. Moreover, in contemporary processes, typically metal-containing structures such as test keys, alignment marks, measurement marks and feature patterns are usually arranged in dicing lanes, in order to result in area savings. Otherwise, if such structures are not arranged in dicing lanes, they would undesirably consume valuable die area, leading to increases in manufacturing cost. In contrast, embodiments disclosed herein propose a dicing method suitable for substrates with different dicing area materials and capable of less destructive dicing with less contamination. Detailed description thereof is set forth below.

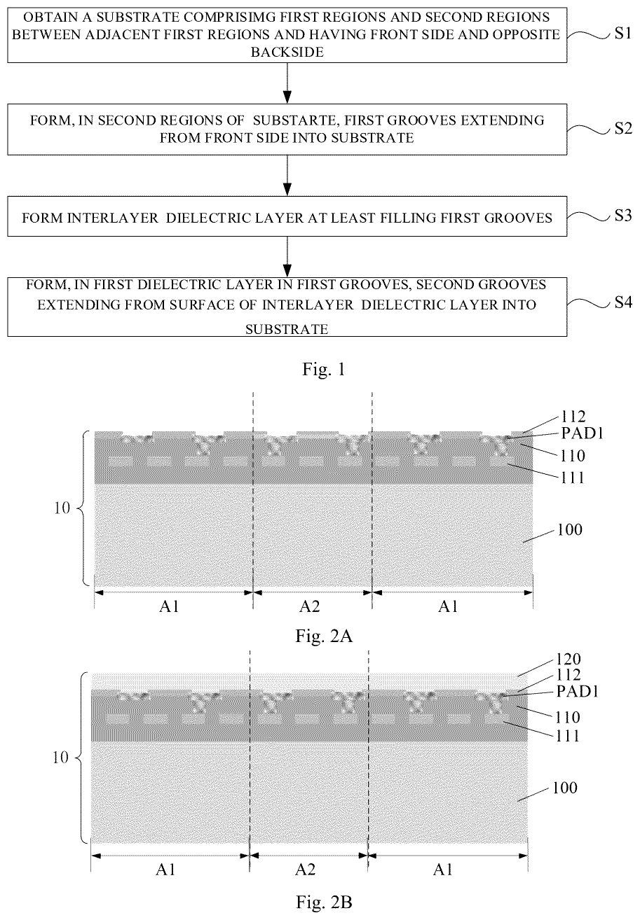

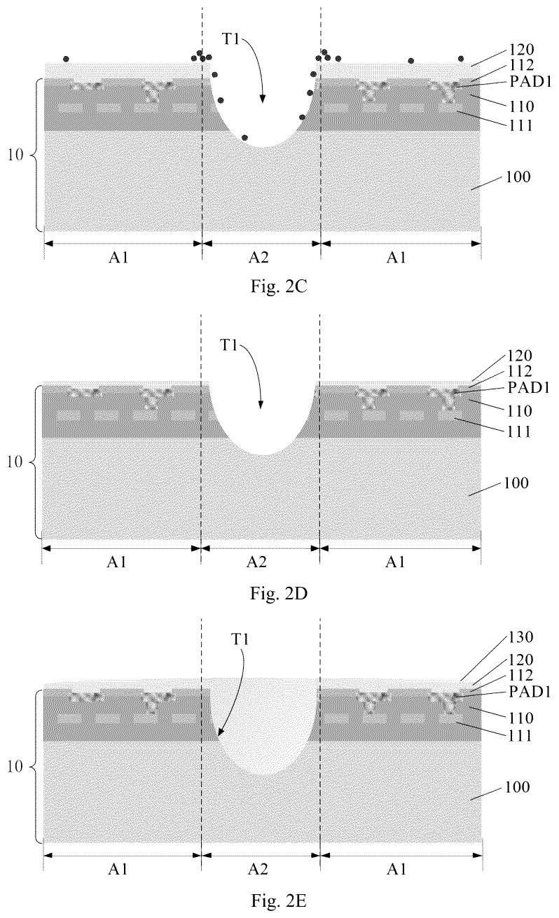

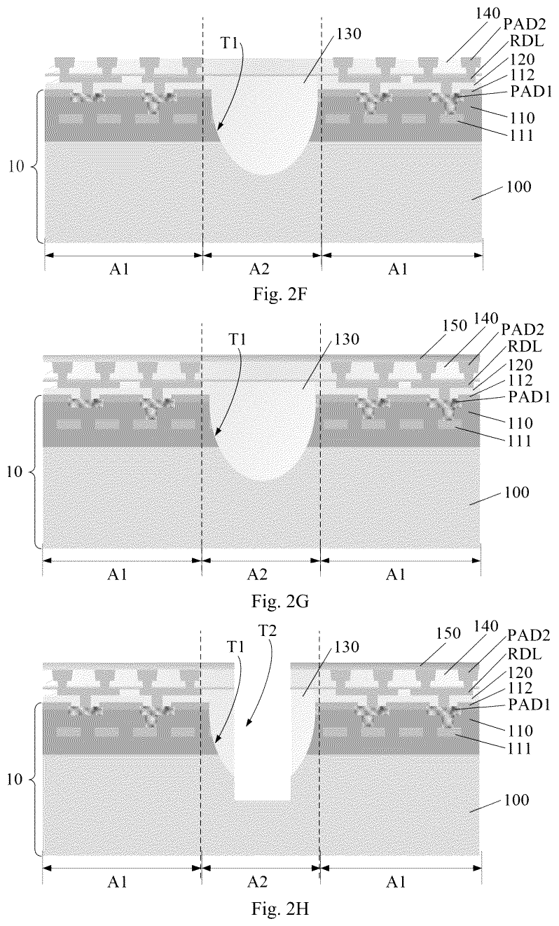

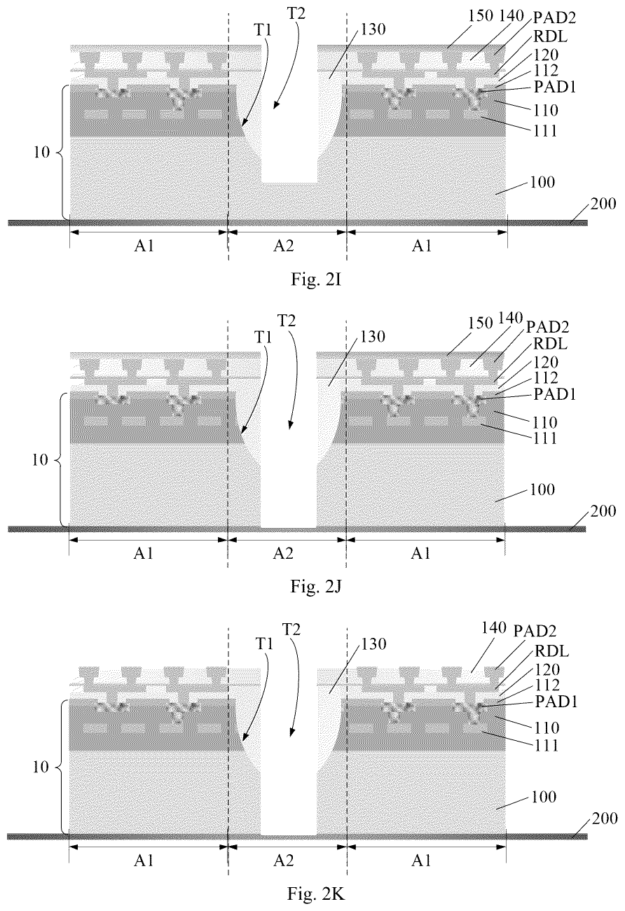

Referring to FIGS. 1 and 2A, in a dicing method according to an embodiment of the present invention, a substrate 10 is obtained, which comprises first regions A1 and a second region A2 between adjacent first regions A1. The substrate 10 has a front side and a backside opposite to the front side.

The dicing method can be used, for example, to dice a wafer to form dies. The substrate 10 is, for example, a wafer. For example, the first region A1 is a die region, and the second region A2 is a dicing lane. The front side of the substrate 10 is, for example, a surface on which devices in the dies are formed. As an example, in the orientation of FIG. 2A, the front side of the substrate 10 is an upper surface thereof, and the backside of the substrate 10 is a lower surface thereof. It will be understood that the dicing method proposed herein is also applicable to situations where the substrate 10 is a non-semiconductor substrate.

As shown in FIG. 2A, the substrate 10 may include a base substrate 100 and an interlayer dielectric layer 110 formed on the base substrate 100. The interlayer dielectric layer 110 contains a metal layer. The base substrate 100 may be silicon, silicon germanium, silicon carbide, silicon on insulator (SOI), germanium on insulator (GOI), silicon germanium on insulator (SiGeOI), a group III-V compound (e.g., gallium nitride or gallium arsenide) base substrate, or other base substrate material well known in the art to carry semiconductor components. The following description is set forth in the context of the base substrate 100 being a silicon base substrate, as an example.

The structure of the substrate 10, such as the components that it contains and the dimensions and layout thereof, may be configured as actually needed. As an example, semiconductor components (not shown) may be formed in surface areas of the base substrate 100 in the first regions A1, such as at least one of MOS devices, sensing elements, storage elements and passive components. Metal interconnect structures 111 (shown as being indicated at 111 only as an example; however, in practice, these may include multiple metal interconnect layers and conductive channels formed between the metal interconnect structure layers) may be formed on top of the semiconductor components, and pads PAD1 are formed above the metal interconnect structures 111. The semiconductor components, the metal interconnect structures 111 and the pads PADI are isolated from one another by a dielectric material while being connected by conductive channels in the dielectric material. A passivation layer 112 may be formed over the dielectric material, and the pads PAD1 may be exposed from openings formed in the passivation layer 112. In the substrate 10, the dielectric material surrounding the metal interconnect structures 111 on the base substrate 100 and the passivation layer 112 make up the interlayer dielectric layer 110. The interlayer dielectric layer 110 may contain a metal layer of various metal materials, and the same or different metals may be provided in the dielectric layer in the first and second regions A1, A2.

As an example, in the second region A2 of the substrate 10, structures may be formed simultaneously with the metal components and dielectric material formed in the first region A1, such as at least one of test keys, alignment marks, measurement marks and feature patterns. The metal material in the second region A2 may be the metal layer formed in the second region A2. The structures in the second region A2 may include more than one material.

Referring to FIGS. 1 and 2C, a first groove T1 is formed in the second region A2 of the substrate 10. The first groove T1 extends from the front side of the substrate 10 into the substrate 10.

As shown in FIG. 2B, before the first groove T1 is formed, a cap layer 120 may be optionally formed on the front side of the substrate 10 in order to protect the surface of the substrate 10 during the subsequent laser dicing process. For example, the cap layer 120 may include silicon oxide, silicon nitride, silicon oxynitride, silicon carbonitride or another suitable material. In the following embodiments, the cap layer 120 is a silicon oxide layer, for example.

As shown in FIG. 2C, for example, the first groove T1 may be formed in the second region A2 of the substrate 10 by removing the interlayer dielectric layer 110 and the metal layer from the second region A2 through a laser dicing process. In other embodiments, the first groove T1 may be formed in the second region A2 of the substrate 10 by removing the interlayer dielectric layer 110 and the metal layer from the second region A2 through another process than laser dicing.

In the laser dicing process, appropriate laser radiation from a nanosecond, picosecond, femtosecond or similar laser device may be irradiated on the second region A2 of the substrate 10. Since laser radiation is not selective for materials to be diced, the materials of the substrate 10 in the second region A2 may be partially removed, forming the first groove T1. The laser dicing process may be so controlled that the metal layer in the second region A2 is removed, facilitating subsequent dicing of the substrate 10 in the second region A2.

Optionally, as shown in FIG. 2C, the first groove T1 may at least extend through the interlayer dielectric layer 110. That is, the depth of the first groove T1 in the substrate 10 is greater than or equal to the thickness of the interlayer dielectric layer 110. This not only allows removal of the metal layer from the second region A2, but can also simplify the structure of the second region A2, making the subsequent dicing easier to carry out. In some embodiments, the first groove T1 may not extend through the interlayer dielectric layer 110. That is, the depth of the first groove T1 in the substrate 10 is less than the thickness of the interlayer dielectric layer 110. In this case, the metal layer may be removed, while a partially thickness of the interlayer dielectric layer 110 is retained between the bottom of the first groove T1 and the base substrate 100. In a direction parallel to the front side of the substrate 10, the first groove T1 may have a cross-sectional width greater than, equal to or less than a cross-sectional width of the second region A2.

Compared with plasma dicing, laser dicing is slower, produces rougher diced surface and is more prone to slag accumulation around dicing regions. Accordingly, according to the embodiments herein, as a result of the laser dicing process, the first groove T1 is formed, instead of the substrate 10 being thermally cut through, in the second region A2. On the one hand, this enables removal of the metal layers from the second region A2. On the other hand, the speed of the overall dicing process is not affected much, and the formation of slag and surface particles is reduced, facilitating cleaning and trimming of the diced surface.

In FIG. 2C, the black dots within and outside the first groove T1 schematically represent slag and surface particles formed during the laser dicing process. In order to ensure cleanliness of the substrate 10 and prevent contamination due to slag and surface particles formed during the laser dicing process, referring to FIGS. 1 and 2D, after the laser dicing process is completed and before an interlayer dielectric layer is filled in the first groove T1, the slag and surface particles are removed from the substrate 10. Here, the term “slag” refers to melt particles arising from heat produced by laser radiation and adhering to the substrate 10, and the term “surface particles” refers to other particles adhering to the substrate 10 than the slag.

The removal of slag and surface particles can be accomplished using various appropriate processes, such as at least one of wet cleaning and chemical mechanical polishing (CMP). For example, a wet cleaning process may be carried out first to at least partially remove the surface particles using a cleaning solution, which may be particularly selected depending on the composition of the surface particles. A CMP process may follow to remove the slag and the remaining surface particles. As shown in FIG. 2D, the cap layer 120 may be thinned in the CMP process. After that, another wet cleaning process may be performed to remove contaminants and particles. After the slag and surface particles are removed, the cap layer 120 may be either retained or removed, as needed.

Optionally, after the slag and surface particles produced in the laser dicing process are removed, surface of the resulting first groove T1 (referred to hereinafter as the “first surface”) may be rounded and smoothed. The first surface of the first groove T1 may be curved, and the rounding and smoothing can reduce the roughness of the surface resulting from the laser dicing process. For example, the rounding and smoothing may be accomplished by a plasma ashing process using a plasma generating gas, which may be selected as needed. The first surface of the first groove T1 includes first side surface and first bottom surface. The first side and bottom surfaces may be joined by smooth or non-smooth transitions therebetween. It will be understood that the first side and bottom surfaces of the first groove T1 may be of any appropriate shape. The first side and/or bottom surfaces of the first groove T1 may be straight or curved. For example, on a cross-section perpendicular to the front side, the first side surface of the first groove T1 may be curved lines, or as straight line oblique or perpendicular to the front side of the substrate 10, and the first bottom surface of the first groove T1 may be curved or straight line.

Referring to FIGS. 1 and 2E, a first dielectric layer 130 is formed, which at least fills the first groove T1. For example, the first dielectric layer 130 may include silicon oxide, silicon nitride, silicon oxynitride, silicon carbonitride or another suitable material. In the following embodiments, the first dielectric layer 130 is a silicon oxide layer, for example.

As shown in FIG. 2E, as an example, the first dielectric layer 130 may not only fill the first groove T1, but may also cover an upper surface of the interlayer dielectric layer 110 outside the first groove T1. In the case of the cap layer 120 being retained, the first dielectric layer 130 may further cover an upper surface of the cap layer 120 outside the first groove T1. In order to improve surface flatness of the first dielectric layer 130, the first dielectric layer 130 may be first deposited to a thickness greater than the depth of the first groove T1 and then planarized (e.g., by CMP) to increase the flatness of its upper surface. As a result of the planarization, the thickness of the first dielectric layer 130 may be less than, equal to or greater than the depth of the first groove T1. The first dielectric layer 130 on the substrate 10 outside the first groove T1 may be either retained or removed.

FIG. 2F is a cross-sectional view showing a second dielectric layer 140 formed on the first dielectric layer 130 on the substrate 10 and, and a metal redistribution layer (RDL) and conductive pads PAD2 formed in the second dielectric layer 140. Referring to FIG. 2F, as an example, die(s) in at least one of the die regions A1 of the substrate 10 may be intended to be subsequently bonded and interconnected with other structure(s). In order to facilitate such bonding to the other structure(s), after the first dielectric layer 130 is formed and before second groove T2 is formed, a second dielectric layer 140 is formed over the front side of the substrate 10 in the first region A1, and conductive pads are formed in the second dielectric layer 140 in the first regions A1. The second dielectric layer 140 may be formed also in the second region A2, but in this case, the second dielectric layer 140 corresponding to the second groove T2 should be metal-free. It will be understood that when the first dielectric layer 130 only fills the first groove T1 without covering the front side of the substrate 10 outside the first groove T1, the thickness of the first dielectric layer 130 may be less than, equal to or greater than the depth of the first groove T1. In this case, the second dielectric layer 140 may be formed only over the front side of the substrate 10 outside the first groove T1, or it may also cover the first dielectric layer 130 in the second region A2. When the first dielectric layer 130 not only fills the first groove T1 but also covers the surface of the substrate 10 outside the first groove T1, the second dielectric layer 140 may be formed only on the first dielectric layer 130 in the first region A1, or it may also cover the first dielectric layer 130 in the second region A2. Referring to FIG. 2F, as an example, the method may accordingly include: forming a second dielectric layer 140 over a surface of the first dielectric layer 130 in the first regions A1 and the second region A2; and forming a metal redistribution layer RDL and conductive pads PAD2 in the second dielectric layer 140 in the first regions A1, the metal redistribution layer RDL is connected to the pads PAD1 in the die regions A1 and the conductive pads PAD2 are connected to the metal redistribution layer RDL. Alternatively, only the conductive pads PAD2 may be formed, while the metal redistribution layer RDL may be omitted. In this case, the conductive pads PAD2 may be exposed from the second dielectric layer 140, or completely buried therein. Still alternatively, only the metal redistribution layer RDL may be formed, while the conductive pads PAD2 may be omitted. In this case, the metal redistribution layer RDL may be exposed from the second dielectric layer 140, or completely buried therein. The second dielectric layer 140 may consist of a single or multiple layers. Regarding the formation of the metal redistribution layer RDL and the conductive pads PAD2, the present invention is not limited to what has been particularly shown and described hereinabove. For example, in an alternative embodiment, the metal redistribution layer RDL and the conductive pads PAD2 may have been formed in the substrate 10 before the first groove T1 is formed. In yet another alternative embodiment, die(s) in at least one of the die regions A1 may be connected to other structure(s) through one or more of the pads PAD1. In this case, the second dielectric layer 140, the metal redistribution layer RDL and the conductive pad PAD2 may not be formed after the first dielectric layer 130 is formed.

Referring to FIGS. 1, 2G and 2H, a second groove T2 is formed in the first dielectric layer 130 in the first groove T1, which extend from the surface of the first dielectric layer 130 into the substrate 10. In the illustrated embodiment, the second dielectric layer 140 is formed on the first dielectric layer 130, the second groove T2 extends from a surface of the second dielectric layer 140 into the substrate 10.

As shown in FIG. 2G, before the second groove T2 is formed, a third dielectric layer 150 may be formed over the front side of the substrate 10 in the first regions A1. The third dielectric layer 150 may cover the conductive pads PAD2. Additionally, the third dielectric layer 150 may be formed also in the second region A2. In this case, the second groove T2 may extend from a surface of the third dielectric layer 150 into the substrate 10.

When forming the second groove T2, the third dielectric layer 150 may serve as a hard mask. The third dielectric layer 150 may be formed of any suitable material as needed. In the illustrated embodiment, the conductive pads PAD2 are formed over the substrate 10. In order to provide protection to the conductive pads PAD2 and prevent metal (e.g., copper) diffusion, the third dielectric layer 150 may be formed of a diffusion-resistant material, such as silicon nitride, silicon oxynitride, nitrogen-doped silicon carbide (NDC) or another dielectric material, or a combination thereof.

For example, the formation of the second groove T2 may include the processes as follows.

First of all, as shown in FIG. 2G, the third dielectric layer 150 is formed, and then a patterned photoresist layer (not shown) formed on the third dielectric layer 150. The patterned photoresist layer has an opening above the first dielectric layer 130 in the first groove T1.

After that, as shown in FIG. 2H, with the patterned photoresist layer serving as a mask, an etching (e.g., wet or dry) or plasma dicing process is carried out, which proceeds from the surface of the third dielectric layer 150 corresponding to the first groove T1 towards the substrate 10 to form the second groove T2. When the third dielectric layer 150 and the second dielectric layer 140 are not formed over the surface of the substrate 10 in the first regions A1 and the second region A2, the first dielectric layer 130 corresponding to the second grooves T2 is removed, and resulting second groove T2 extends from the surface of the first dielectric layer 130 into the substrate 10. When the second dielectric layer 140 is, but the third dielectric layer 150 is not, formed over the surface of the substrate 10 in the first regions A1 and the second region A2, the second dielectric layer 140 and the first dielectric layer 130 corresponding to the second groove T2 is removed, and the resulting second groove T2 extends from the surface of the second dielectric layer 140 into the substrate 10. When the third dielectric layer 150 and the second dielectric layer 140 are both formed over the surface of the substrate 10 in the first regions A1 and the second region A2, the third dielectric layer 150, the second dielectric layer 140 and the first dielectric layer 130 (and, optionally, the base substrate 100) are successively etched through to remove the third dielectric layer 150, the second dielectric layer 140 and the first dielectric layer 130 corresponding to the second groove T2, and the resulting second groove T2 extend from the surface of the third dielectric layer 150 into the substrate 10. It will be understood that those skilled in the art may employ other techniques than etching and plasma dicing to form the second groove T2.

The second groove T2 may have second surface including second side surface and second bottom surface, which may be joined by smooth or non-smooth transitions therebetween. It will be understood that the second side and bottom surfaces of the second groove T2 may be of any appropriate shape. The second side and/or bottom surfaces of the second groove T2 may be straight or curved. For example, on a cross-section perpendicular to the front side, the second side surface of the second groove T2 may be a curved line, or as a straight line oblique or perpendicular to the front side of the substrate 10, and the second bottom surface of the second grooves T2 may be a curved or a straight line. In the illustrated embodiment, the second bottom surface of the second groove T2 may lie within the base substrate 100, for example. In this way, subsequent plasma dicing can be achieved in the second region A2 simply by cutting through the base substrate 100, entailing a simpler and more efficient dicing process. The formation of the second groove T2 may be accomplished by anisotropic dry etching. This enables the second side surface of the resulting second groove T2 to be smooth and substantially perpendicular to the front side of the substrate 10, helping optimize the morphology of side surfaces of the resulting dies and increase dicing accuracy. In an alternative embodiment, for example, the second bottom surface of the second groove T2 may lie within the first dielectric layer 130. For example, a width of the second groove T2 may be less than, or equal to, a width of the first groove T1. Additionally, the second side surface of the second groove T2 may be, for example, internal to the first side surface of the first groove T1. For example, the second groove T2 may have a depth less than, equal to or greater than the depth of the first groove T1. Preferably, a width of the second groove T2 is less than a width of the first groove T1, and a depth of the second groove T2 in the substrate 10 is greater than a depth of the first groove T1 in the substrate 10.

Referring to FIGS. 1 and 2K, with the patterned third dielectric layer 150 as a mask, another etching or plasma dicing process is carried out to deepen the second grooves T2 until the substrate 10 is separated. In this process, the second side surface of the second groove T2 gradually extend downwards, and the second bottom surface are gradually lowered in the substrate 10.

The first dielectric layer 130 may be provided between the first surface of the first groove T1 and the second surface of the second groove T2. In the case of the second bottom surface of the second groove T2 lying within the first dielectric layer 130, the first dielectric layer 130 may be provided between the first side surface of the first groove T1 and the second side surface of the second groove T2 and between the first bottom surface of the first groove T1 and the second bottom surface of the second groove T2. In the case of the second bottom surface of the second groove T2 lying within the base substrate 100, the first surface of the first groove T1 may intersect with the second surface of the second groove T2, and the first dielectric layer 130 may be provided between the first side surface of the first groove T1 and the second side surface of the second groove T2.

As an example, the following processes may be carried out on the structure of FIG. 2H.

As shown in FIG. 2I, the substrate 10 may be back-thinned and then placed on a carrier tape 200. The carrier tape 200 is used to fix the substrate 10 and the resulting dies, helping increase the integrity of the dies during dicing and reduce their risk of breakage, undesired displacement or falling off. For example, the carrier tape 200 may be a UV tape. In some embodiments, the substrate 10 may not be thinned, if required.

As shown in FIG. 2J, with the patterned third dielectric layer 150 being used as a mask, a plasma dicing process may be performed on the base substrate 100 exposed in the second groove T2 to remove the base substrate 100 underlying the second groove T2, thereby separating and singularizing the dies in the respective die regions. According to embodiments of the present invention, plasma dicing is preferred over blade dicing and laser cutting because it allows the resulting dies to have smooth side surface and desirable flatness. Moreover, the dies are less contaminated because byproducts generated during the dicing process can be carried away by the process gas.

As shown in FIG. 2K, the third dielectric layer 150 may be removed, before the resulting dies are, for example, packaged or bonded to another structure, depending on whether the pads PAD1 (e.g., in the case of the conductive pads PAD2 not being formed) or the conductive pads PAD2 are exposed. The die obtained according to the dicing method discussed above may each be boned and interconnected with an underlying substrate, for example, at the surface with the conductive pads PAD2. The bonding and interconnection may be accomplished using a hybrid bonding technique. Since the die obtained according to the dicing method discussed above has high surface cleanliness favored by the hybrid bonding technique, high yield can be expected.

In the dicing method discussed above, the first groove T1 is formed in the second region A2 of the substrate 10 and filled with the first dielectric layer 130, and the second groove T2 is then formed in the first dielectric layer 130 in the first groove T1. The first groove T1 is formed by removing corresponding portions of the substrate 10 that are in the first groove T1, and the second groove T2 is formed by etching the first dielectric layer 130 in the first groove T1. Compared with forming the second groove T2 by directly removing corresponding portions in the second regions A2, this dicing method can be suitably used to dice regions of various different materials and enables easier dicing with less destructiveness and contamination of a substrate 10, resulting in improved dicing quality.

Embodiments of the present invention also relate to a semiconductor structure obtainable according to the dicing method described above.

Referring to FIG. 2H, the semiconductor structure includes a substrate 10. The substrate 10 comprises first regions A1 and at least one second region A2 between adjacent first regions A1. The substrate 10 has a front side and a backside opposite to the front side. For example, the substrate 10 may be a wafer, the first regions A1 is a die region, and the second region A2 is a dicing lane. The front side of the substrate 10 may be, for example, a surface on which devices in the dies are formed. As an example, in the orientation of FIG. 2H, the front side of the substrate 10 is an upper surface thereof, and the backside of the substrate 10 is a lower surface thereof.

The semiconductor structure further includes a first dielectric layer 130 and a first groove T1 and a second groove T2 formed in the second region A2 of the substrate 10. The first groove T1 extends from the front side of the substrate 10 into the substrate 10 and the first dielectric layer 130 at least fills the first groove T1. The second groove T2 is formed in the first dielectric layer 130 in the first groove T1 and extends from a surface of the first dielectric layer 130 into the substrate 10.

In some embodiments, the substrate 10 includes a base substrate 100 and an interlayer dielectric layer 110 formed on the base substrate 100. The interlayer dielectric layer 110 is formed on the front side of the substrate 10, and the first groove T1 at least extend through the interlayer dielectric layer 110.

As shown in FIG. 2H, the semiconductor structure may further include a second dielectric layer 140 and conductive pads PAD2. The second dielectric layer 140 is formed in both the first regions A1 and the second region A2 and covers the first dielectric layer 130. In this case, in the second region A2, the second groove T2 extends from a surface of the second dielectric layer 140 into the substrate 10. The conductive pads PAD2 are formed in the second dielectric layer 140 in the first region A1, and the second dielectric layer 140 in the second region A2 is metal-free. The semiconductor structure may further include a third dielectric layer 150, which is formed in the first regions A1 and the second region A2 and covers the second dielectric layer 140. In this case, in the second regions A2, the second groove T2 extends from a surface of the third dielectric layer 150 into the substrate 10. For more details of relative locations of the first dielectric layer 130, the second dielectric layer 140 and the third dielectric layer 150, reference can be made to the above description, and repeated description thereof is omitted herein.

Embodiments of the present invention also relate to a die obtainable according to the dicing method described above.

FIG. 2K shows two dies obtained by dicing a substrate 10. According to embodiments of the present invention, each die has a first die surface and a second die surface opposite to the first die surface. Each die also has a first surface and a second surface. The first surface is a surface of a first groove T1 formed by removing part of the substrate 10, and the second surface is a surface of a second groove T2 formed by etching a first dielectric layer 130 filled in the first groove T1. The first and second surfaces are located between the first and second die surfaces and intersect with each other at an edge of the die. The first dielectric layer 130 is provided between the first and second surfaces.

In a semiconductor structure construed in accordance with embodiments of the present invention, first groove T1 and second groove T2 are formed in second region A2 of a substrate 10, and the substrate 10 can be separated along the second groove T2. The second groove T2 extends from a surface of a first dielectric layer 130 into the substrate 10. With this arrangement, the semiconductor structure has improved quality and can be diced into individual dies in a manner with less destructiveness and contamination.

It is noted that the embodiments disclosed herein are described in a progressive manner, with the description of each embodiment focusing on its differences from others. Cross-reference can be made between the embodiments for their common or similar features.

While the invention has been described above with reference to several preferred embodiments, it is not intended to be limited to these embodiments in any way. In light of the teachings hereinabove, any person of skill in the art may make various possible variations and changes to the disclosed embodiments without departing from the scope of the invention. Accordingly, any and all such simple variations, equivalent alternatives and modifications made to the foregoing embodiments without departing from the scope of the invention are intended to fall within the scope thereof.

1-20. (canceled)

21. A dicing method, comprising:
obtaining a substrate that comprises at least two first regions and at least one second region located between adjacent first regions, wherein the substrate has a front side and a backside opposite to the front side;
forming a first groove in each second region of the substrate, wherein the first groove extends from the front side into the substrate;
forming a first dielectric layer that at least fills the first groove; and
forming a second groove in the first dielectric layer in each first groove, wherein the second groove extends from a surface of the first dielectric layer into the substrate.

22. The dicing method of claim 21, wherein the substrate comprises a base substrate, an interlayer dielectric layer formed over the base substrate and a metal layer formed in the interlayer dielectric layer in the second region, wherein the first groove is formed in the second region of the substrate by removing a portion of the interlayer dielectric layer and a portion of the metal layer in the second region through a laser dicing process.

23. The dicing method of claim 22, wherein slag and surface particles produced during the laser dicing process are removed before the first dielectric layer is formed.

24. The dicing method of claim 22, wherein the first groove at least extends through the interlayer dielectric layer.

25. The dicing method of claim 21, wherein before the second groove is formed, a second dielectric layer is formed in the first and second regions, wherein at least one conductive pad is formed in the second dielectric layer in the first region, wherein the second dielectric layer corresponding to the second groove is metal-free, and wherein the second groove extends from a surface of the second dielectric layer into the substrate.

26. The dicing method of claim 25, wherein before the second groove is formed, forming a third dielectric layer in the first and second regions, wherein the third dielectric layer covers the conductive pad, and
wherein performing a plasma dicing process from a surface of the third dielectric layer that corresponds to the first groove into the substrate, thereby forming the second groove until the substrate is separated.

27. The dicing method of claim 26, wherein before the substrate is separated by the plasma dicing process, the substrate is thinned from the backside and then the backside of the thinned substrate is placed on a carrier tape.

28. The dicing method of claim 21, wherein the substrate is a wafer, and wherein the first region is a die region and the second region is a dicing lane.

29. A semiconductor structure, comprising:
a substrate that comprises at least two first regions and at least one second region located between adjacent first regions, wherein the substrate has a front side and a backside opposite to the front side;
a first groove formed in the second region of the substrate and extending from the front side into the substrate;
a first dielectric layer at least filling the first groove; and
a second groove formed in the first dielectric layer in the first groove and extending from a surface of the first dielectric layer into the substrate.

30. The semiconductor structure of claim 29, wherein the substrate comprises a base substrate and an interlayer dielectric layer located over the base substrate, wherein the first groove at least extends through the interlayer dielectric layer.

31. The semiconductor structure of claim 29, further comprising:
a second dielectric layer formed in the first and second regions and covering the first dielectric layer, wherein the second groove extends from a surface of the second dielectric layer into the substrate; and
at least one conductive pad formed in the second dielectric layer in the first region.

32. The semiconductor structure of claim 31, further comprising a third dielectric layer formed in the first and second regions and covering the conductive pad, wherein the second groove extends from a surface of the third dielectric layer into the substrate.

33. The semiconductor structure of claim 29, wherein the second groove extends through a bottom of the first groove.

34. A die, comprising:
a first die surface and a second die surface opposite to the first die surface;
a first surface that is a surface of a first groove formed by removing a portion of a substrate; and
a second surface that is a surface of a second groove formed by etching a first dielectric layer filled in the first groove, wherein the first and second surfaces are located between the first and second die surfaces and intersects with each other at an edge of the die, and wherein the first dielectric layer is provided between the first and second surfaces.
